(19) United States
(12) Patent Application Publication
(10) Pub. No.: US 2003/0128068 A1
(43) Pub. Date: Jul. 10, 2003

(54) Low noise image-reject gm-c filter

(76) Inventors: Farbod Behbahani, Irvine, CA (US); Siamak Delshad-Pour, Aliso Viejo, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/222,748

(22) Filed: Aug. 16, 2002

Related U.S. Application Data
(60) Provisional application No. 60/313,139, filed on Aug. 16, 2001.

(51) Int. Cl. H03B 1/00

(52) U.S. Cl. 327/552

(57) ABSTRACT

A polyphase filter having a DC offset cancellation network is disclosed. The polyphase filter includes a first filter section to generate a first set of I- and Q- output signals, a second filter section to generate a second set of I- and Q- output signals, and a DC offset cancellation feedback device to generate four DC offset cancellation signals such that when combined with the input I- and Q- signals, the level of DC offset within the polyphase filter is substantially reduced. Also, a transconductance cell useful for the polyphase filter is disclosed. The transconductance cell includes a first pair of FETs having common gates to receive an input signal and common drains to generate a complementary output signal, a second pair of FETs having common gates to receive a complementary input signal and common drains to generate an output signal, and tail current FET to control the transconductance.

### CROSS-REFERENCE TO A RELATED APPLICATION

This application claims the benefit of the filing date of Provisional Patent Application No. 60/313,139, filed on Aug. 16, 2001, and entitled “Low Noise Image-Reject GM-C Filter with New Transconductance Cell”, which is herein incorporated by reference.

### FIELD OF THE INVENTION

This invention relates generally to image-reject filters as used in receivers, and in particular, to a low noise image reject gm-c polyphase filter.

### BACKGROUND OF THE INVENTION

Polyphase filters are typically employed in radio frequency (RF) signal receiving applications. Specifically, these filters are used to remove any image signals generated during the down-converting or demodulating stages. A typical receiver includes a low noise amplifier (LNA) to boost the signal level of the received signal while minimizing the amplifier noise added to the signal. Following the LNA stage, a mixer or quadrature mixer is employed to down-convert the received signal to a lower frequency range. The down-converting typically generates the desired signal plus an image signal on the mirror side of the local oscillator signal. To eliminate the image signal, band pass filters, low pass filter, or other types of filters are employed. If a quadrature mixing stage is used which generates I and Q outputs, polyphase filters are used to remove the image signal.

FIG. 1 illustrates a block diagram of an exemplary receiver 100 using a prior art image-reject polyphase filter. The receiver 100 consists of a signal source 102 such as an antenna including an LNA to boost the received signal. The receiver 100 further consists of a quadrature demodulator 104 to down-convert and generate the I and Q phases of the received signal. As previously discussed, the down-converted I and Q signals may each include an image signal which needs to be substantially filtered out. Accordingly, the receiver 100 further consists of a polyphase filter 106 including a first polyphase low pass filter (LPF) section 106a coupled to a second polyphase LPF section 106b.

There are several undesirable characteristics of the prior art polyphase filter 106. One such characteristic relates to possible DC offset present at the I and Q inputs to the polyphase filter 106 add space. DC offset present at the I and Q inputs to the polyphase filter 106 may saturate and/or imbalance the output of the filter 106. This DC offset may further degrade the linearity of the receiver 100. In the prior art, DC blocking capacitors are employed at the inputs and outputs of the polyphase filter 106 to reduce DC offset problems. However, at low frequency filtering applications, the DC blocking capacitors need to be large, which makes it difficult to implement them in integrated circuit. To overcome this problem, another approach of reducing DC offset problems is by using a DC servo loop.

FIG. 2 illustrates a block diagram of a prior art servo loop 200 used for DC offset cancellation. The servo loop 200 consists of an adder 202, a main amplifier 204, an error amplifier 206, and a low pass filter (LPF) 208. An input signal having an undesired DC offset may be present at the input of the main amplifier 204. The main amplifier 204 amplifies the input signal along with the DC offset. The DC offset at the output of the main amplifier 204 represents an error. The error amplifier 206 generates an error signal which varies as a function of the DC offset at the output of the main amplifier. The low pass filter (LPF) 208 generates the DC offset portion of the error signal which is inversely applied to the adder 202. In theory, the DC offset error signal cancels the DC offset present in the input signal.

One problem with the servo loop approach is that it does not work well at canceling DC offset for polyphase filters. The reason being is that an output of a polyphase filter is a function of all of its inputs due to the interconnections of the two filter sections. Thus, the I_{OUT} of the polyphase filter 106 varies a function of both the I_{IN} and I_{OUT}. Similarly, the Q_{OUT} vanes as a function of both I_{IN} and I_{OUT}. Accordingly, the DC offset at the outputs I_{OUT} and Q_{OUT} vary as a function of the DC offsets at both inputs I_{IN} and I_{OUT}. Thus, the servo loop method, which is useful for only single-input/single output applications, does not work well for canceling DC offset for polyphase filters.

FIG. 3 illustrates a block diagram of a prior art transconductance stage 300 used in a polyphase filter. Another drawback of the prior art polyphase filter is the use of its transconductance stage 300. The transconductance stage 300 consists of input field effect transistors (FETs) Q1 and Q2 having their gates coupled in common to receive an input signal, their drains coupled in common, and their sources coupled respectively to V_{DD} and ground potential. In addition, the transconductance stage 300 consists of output field effect transistors (FETs) Q3 and Q4 having their gates and drains coupled in common, to the drains of transistors Q1 and Q2 and to generate the transconductance output, and their sources coupled respectively to V_{DD} and ground potential.

A drawback of the prior art transconductance stage 300 is that the output transistors Q3 and Q4, acting as an active load for the transconductance stage 300, add noise to the output current, while not adding to the transconductance. Therefore, the noise added by the prior art transconductance stage degrades the received signal of the receiver 100.

### BRIEF DESCRIPTION OF THE DRAWINGS

FIG. 1 illustrates a block diagram of a communications system using a prior art image-reject polyphase filter;

FIG. 2 illustrates a block diagram of a prior art servo loop used for DC offset cancellation;

FIG. 3 illustrates a block diagram of a prior art transconductance stage used in a polyphase filter;

FIG. 4 illustrates a block diagram of an exemplary communications system using an image-reject polyphase filter in accordance with an embodiment of the invention;

FIG. 5 illustrates a schematic diagram of an exemplary image-reject polyphase filter in accordance with another embodiment of the invention;

FIG. 6 illustrates a schematic diagram of an exemplary transconductance stage in accordance with another embodiment of the invention; and

FIG. 7 illustrates a schematic diagram of an exemplary bias control loop for the exemplary transconductance stage in accordance with another embodiment of the invention.

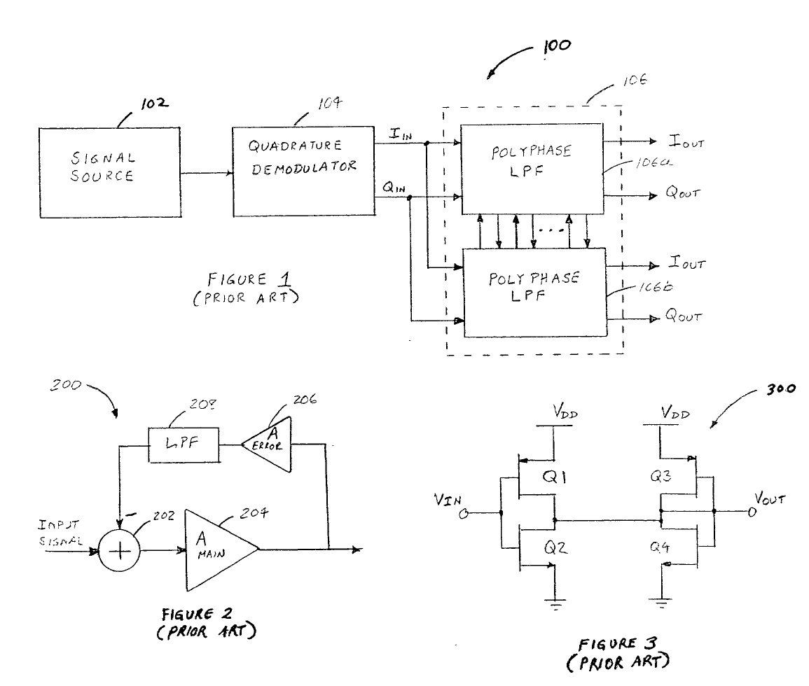

### DETAILED DESCRIPTION OF THE INVENTION

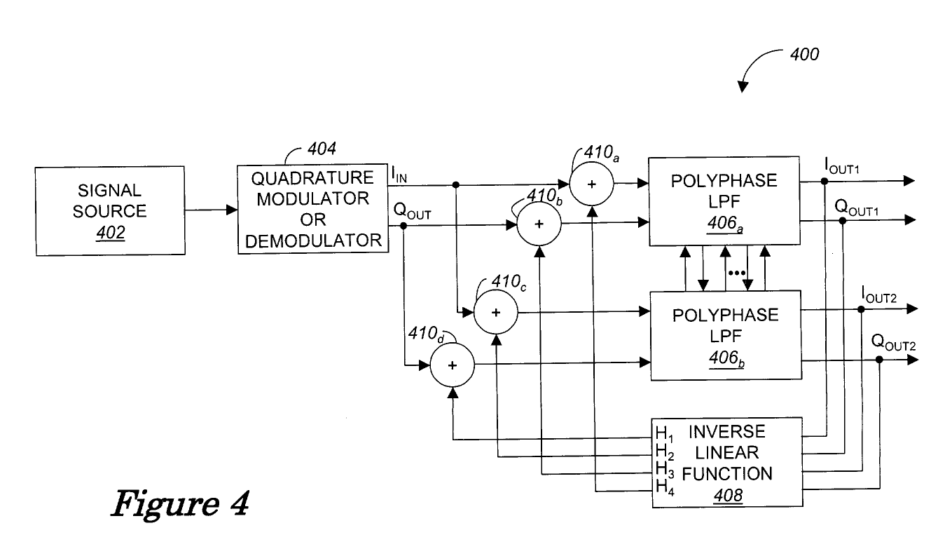

FIG. 4 illustrates a block diagram of an exemplary communications system 400 using an image-reject polyphase filter in accordance with an embodiment of the invention. The communications system 400 can be configured as a receiver and/or transmitter. The communications system 400 comprises a signal source 402 such as an antenna and/or LNA in the case of a receiver or a baseband subsystem in the case of a transmitter. The communications system 400 further comprises a quadrature demodulator (in the case of a receiver) or modulator (in the case of a transmitter) 404 to generate the I- and Q- input signals. In addition, the communications system 400 comprises a polyphase filter 406 to substantially reduce the power level of any image signal generated by the quadrature demodulator or modulator 404.

The polyphase filter 406, in turn, comprises a first polyphase filter section 406a, a second polyphase filter section 406b, an inverse linear transfer function section 408, and four adders 410a-d. The first and second polyphase filters 406a-b may be configured as low pass filters, band pass filters, or other types of polyphase filters. As customary of polyphase filters, the first and second polyphase filters 406a-b include a plurality of interconnections between the two filters 406a-b. The inverse linear transfer function 408 includes four inputs coupled respectively to the four outputs of the polyphase filters sections 406a-b, and includes four outputs coupled respectively to the adders 410a-d. The I-signal output of the quadrature demodulator or modulator 404 is coupled to adders 410a and 410c. Also, the Q-signal output of the quadrature demodulator or modulator 404 is coupled to adders 410b and 410d.

As previously discussed in the Background section, each output of the polyphase filter 406 is a function of the four inputs to the filter 406. Accordingly, the DC offset at each output of the polyphase filter 406 is a function of the various DC offsets at the two inputs to the polyphase filter 406. In order to substantially reduce the DC offset at the outputs of the polyphase filter 406, the inverse linear function 408 includes four transfer functions which are inverse to the transfer function of the outputs of the polyphase filter 406 at a frequency near zero (e.g. at DC). Hence, the following relationships substantially hold for the transfer functions H₁₋₄ of the inverse linear function 408:

a. H₁=I_{OUT1} ƒ⁻¹(I_{IN}, Q_{IN}) @ freq.˜0

b. H₂=Q_{OUT1} ƒ⁻¹(I_{IN}, Q_{IN}) @ freq.˜0

c. H₃=I_{OUT2} ƒ⁻¹(I_{IN}, Q_{IN}) @ freq.˜0

d. H₄=Q_{OUT2} ƒ⁻¹(I_{IN}, Q_{IN}) @ freq.˜0

where I_{OUT1} ƒ⁻¹ (I_{IN}, Q_{IN}) @freq.˜0 is the inverse transfer function for I_{OUT1} as a function of the inputs I_{IN}, Q_{IN} at a frequency approximately zero, Q_{OUT1} ƒ⁻¹(I_{IN}, Q_{IN}) @ freq.˜0 is the inverse transfer function for Q_{OUT1} as a function of the inputs I_{IN}, Q_{IN} at a frequency approximately zero, I_{OUT2} ƒ⁻¹(I_{IN}, Q_{IN}) @ freq.˜0 is the inverse transfer function for I_{OUT2} as a function of the inputs I_{IN}, Q_{IN} at a frequency approximately zero, and Q_{OUT2} ƒ⁻¹(I_{IN}, Q_{IN}) @ freq.˜0 is the inverse transfer function for Q_{OUT2} as a function of the inputs I_{IN}, Q_{IN} at a frequency approximately zero.

Since the inverse transfer function 408 generates DC offset cancellation signals by taking the inverse functions at approximately zero frequency for the respective outputs of the polyphase filter as a function of the inputs I_{IN}, Q_{IN}, the addition of the DC offset cancellation signals with the inputs I_{IN}, Q_{IN} by the respective adders 410a-d substantially cancels out any DC offset at the output of the polyphase filter 406.

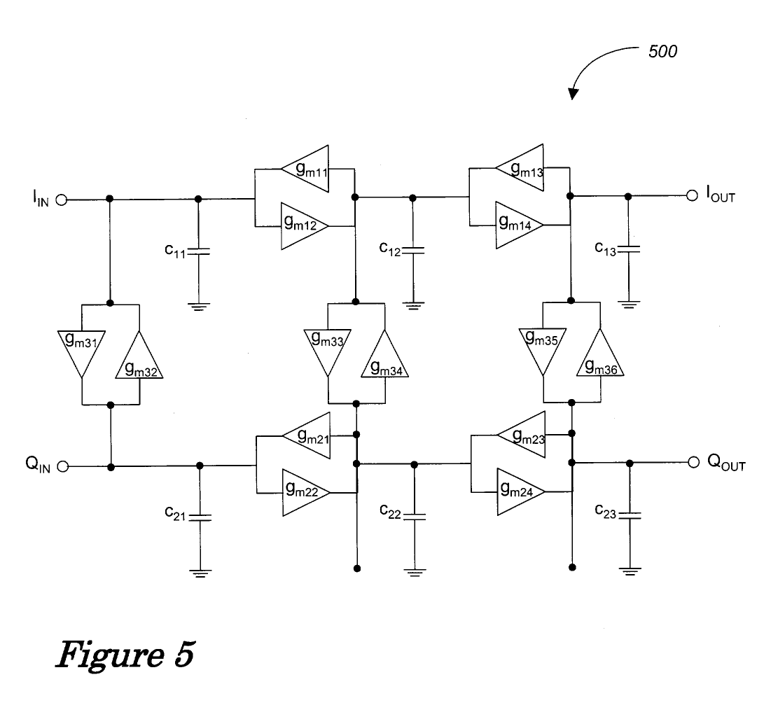

FIG. 5 illustrates a schematic diagram of an exemplary image-reject polyphase filter 500 in accordance with another embodiment of the invention. The polyphase filter comprises a first filter section coupled between the I-signal input and the I-signal output, and comprising capacitors C₁₁, C₁₂, and C₁₃, and transconductance stages gₘ₁₁, gₘ₁₂, gₘ₁₃, and gₘ₁₄. The capacitors C₁₁, C₁₂, and C₁₃ are connected in-shunt with a pair of circularly-connected transconductance stages gₘ₁₁, and gₘ₁₂ connected in-series between shunt capacitors C₁₁, and C₁₂, and another pair of circularly-connected transconductance stages gₘ₁₃ and gₘ₁₄ connected in-series between shunt capacitors C₁₂ and C₁₃.

The polyphase filter 500 further comprises a second filter section 500 coupled between the Q-signal input and the Q-signal output, and comprising capacitors C₂₁, C₂₂, and C₂₃, and transconductance stages gₘ₁, gₘ₂₂, gₘ₂₃, and gₘ₂₄. The capacitors C₂₁, C₂₂, and C₂₃ are connected in-shunt with a pair of circularly-connected transconductance stages gₘ₂₁ and gₘ₂₂ connected in-series between shunt capacitors C₂₁ and C₂₂, and another pair of circularly-connected transconductance stages gₘ₂₃ and gₘ₂₄ connected in-series between shunt capacitors C₂₂ and C₂₃.

The first and second filter sections are interconnected by three circularly-connected transconductance stages. Specifically, a pair of circularly-connected transconductance stages gₘ₃₁ and gₘ₃₂ are connected from the I-signal input to the Q-signal input. Another pair of circularly-connected transconductance stages gₘ₃₅ and gₘ₃₆ are connected from the I-signal output to the Q-signal output. And, another pair of circularly-connected transconductance stages gₘ₃₃ and gₘ₃₃ are connected from shunt capacitor C₁₂ to shunt capacitor C₂₂.

The polyphase filter 500 can be configured as a low pass filter (LPF) or band pass filter (BPF) depending on the values of the capacitors and the transconductances. A pair of circularly-connected transconductance simulates an inductive impedance. As previously discussed in the Background section, the prior art transconductance stage include output transistors that add noise to the output current, while not adding to the transconductance. Thus, an improved transconductance stage is described below.

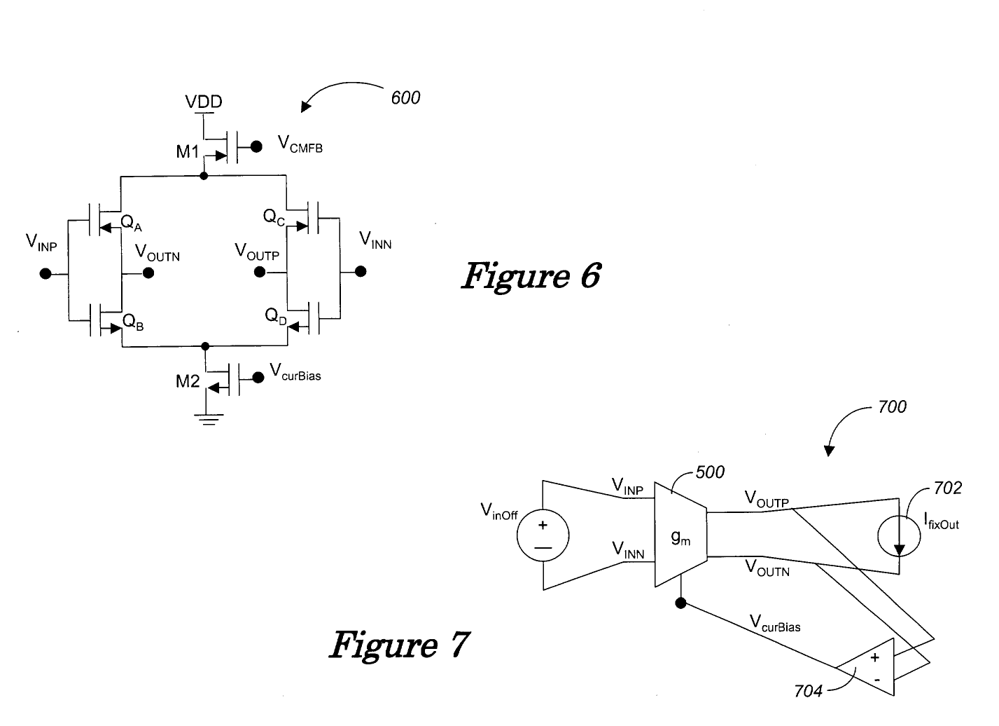

FIG. 6 illustrates a schematic diagram of an exemplary transconductance stage 600 in accordance with another embodiment of the invention. The transconductance stage 600 comprises a first pair of field effect transistors (FETs) Q_{A} and Q_{B} having their gates connected together, their drains connected in together, and their sources connected to the respective sources of FETs M1 and M2. The transconductance stage 600 further comprises a second pair of FETs Q_{C} and Q_{D} having their gates connected together, their drains connected in together, and their sources connected to the respective sources of FETs M1 and M2. The drains of FETs M1 and M2 are connected respectively to V_{DD} and ground potential.

The input signal V_{INP} and its complementary signal V_{INN} are applied to the respective gates of FETs Q_{A-B} and FETs Q_{C-D}. The output signal V_{OUTP} and its complementary signal V_{OUTN} are taken off the respective drains of FETs Q_{C-D} and FETs Q_{A-B}. A bias signal V_{CMFB} is applied to the gate of FET M1 to control the biasing of the transistors Q_{A-D}. Also a tail current control feedback signal is applied to the gate of FET M2 to control the current through the FETs, and therefore the transconductance gain. Since the inputs V_{INP} and V_{INN} are applied to the gates of both the NMOS FETs Q_{B} and Q_{D} and the PMOS FETs Q_{A} and Q_{C}, they all add to the transconductance and act as active loads for one another. Therefore, effectively the noise of the transconductance stage is as low as the noise of one MOS transistor.

FIG. 7 illustrates a schematic diagram of an exemplary bias control loop 700 for the exemplary transconductance stage 500 in accordance with another embodiment of the invention. The input signal V_{INP} and its complementary signal V_{INN} are applied to the transconductance stage 500, which generates the output signal V_{OUTP} and its complementary signal V_{OUTN}. The bias control loop 700 comprises a reference current source 702 to generate a constant current I_{fixOut} and differential amplifier 704. The reference current source 702 is connected on opposite ends respectively to the outputs of the transconductance stage 500. The positive and negative input terminals of the differential amplifier 704 are connected respectively to the outputs V_{OUTP} and V_{OUTN} of the transconductance stage 500. The output of the differential amplifier 704 generates the transconductance gain control signal V_{CURBIAS}, and is coupled to the gate of FET M2.

In operation, if the transconductance stage 500 generates a current different than the reference current I_{fixOut}, a voltage differential appears at the inputs to the differential amplifier 704. In response to this voltage differential, the differential amplifier 704 changes its output (i.e. the transconductance gain control signal V_{CURBIAS}) to substantially equalize its input voltages. The changing of the transconductance gain control signal V_{CURBIAS} changes the transconductance of the stage 500 until the output current substantially equal to the reference current I_{fixout}. When this occurs, the transconductance is equal to the desired transconductance for the stage 500 as determined by the reference current I_{fixOut}.

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than a restrictive sense.

What is claimed is:

1. An apparatus comprising:
a first polyphase filter section to generate first I-signal output and first Q-signal output;
a second polyphase filter section to generate second I-signal output and second Q-signal output, wherein said second polyphase filter is interconnected with said first polyphase filter;
an inverse linear transfer function device to generate a first DC offset cancellation signal for said first I-signal output, a second DC offset cancellation signal for said first Q-signal output, a third DC offset cancellation signal for said second I-signal output, and a fourth DC offset cancellation signal for said second Q-signal output;
a first adder to generate a first signal input to said first polyphase section by adding said first DC offset cancellation signal to said I-signal input;
a second adder to generate a second signal input to said first polyphase section by adding said second DC offset cancellation signal to said Q-signal input;
a third adder to generate a third signal input to said second polyphase section by adding said third DC offset cancellation signal to said I-signal input; and
a fourth adder to generate a fourth signal input to said second polyphase section by adding said first DC offset cancellation signal to said Q-signal input.

2. The apparatus of claim 1, wherein said first polyphase filter section and/or second polyphase filter section is configured as a low pass filter section.

3. The apparatus of claim 1, wherein said first polyphase filter section and/or second polyphase filter section is configured as a band pass filter.

4. The apparatus of claim 1, further comprising a quadrature demodulator to generate said I-signal and Q-signal inputs.

5. The apparatus of claim 4, further comprising a signal source to generate an input signal for said quadrature demodulator.

6. The apparatus of claim 5, wherein said signal source comprises an antenna and/or a low noise amplifier.

7. The apparatus of claim 1, further comprising a quadrature modulator to generate said I-signal and Q-signal inputs.

8. The apparatus of claim 1, further comprising a signal source to generate an input signal for said quadrature modulator.

9. A method comprising:
generating first and second filtered I-signals and first and second filtered Q-signals;
generating first, second, third and fourth DC offset cancellations signals respectively from said first and second filtered I-signals and first and second filtered Q-signals; and
reducing first and second DC offsets residing respectively in an I-signal input and a Q-signal input by combining said first DC offset cancellation signal with said I-signal input, said second DC offset cancellation signal with said Q-signal input, said third DC offset cancellation signal with said I-signal input, and said fourth DC offset cancellation signal with said Q-signal input.

10. The method of claim 9, wherein generating said first DC offset cancellation signal comprises applying said first filtered I-signal to a transfer function that is inverse of a filtering transfer function that generates said first filtered I-signal at a frequency approximately zero.

11. The method of claim 9, wherein generating said second DC offset cancellation signal comprises applying said first filtered Q-signal to a transfer function that is inverse of a filtering transfer function that generates said first filtered Q-signal at a frequency approximately zero.

12. The method of claim 9, wherein generating said third DC offset cancellation signal comprises applying said second filtered I-signal to a transfer function that is inverse of a filtering transfer function that generates said second filtered I-signal at a frequency approximately zero.

13. The method of claim 9, wherein generating said fourth DC offset cancellation signal comprises applying said second filtered Q-signal to a transfer function that is inverse of a filtering transfer function that generates said second filtered Q-signal at a frequency approximately zero.

14. An apparatus comprising:
a transconductance cell comprising:
a first FET including a first source, a first gate, and a first drain;
a second FET including a second source, a second gate, and a second drain, wherein said first and second gates are coupled together to receive an input signal, and said first and second drains are coupled together to generate a complementary output signal;
a third FET including a third source, a third gate, and a third drain; and
a fourth FET including a fourth source, a fourth gate, and a fourth drain, wherein said third and fourth gates are coupled together to receive a complementary input signal, and said third and fourth drains are coupled together to generate an output signal.

15. The apparatus of claim 14, further comprising a fifth FET including a fifth source, a fifth gate, and a fifth drain, wherein said fifth drain is coupled to said second and fourth drains, and said fifth source is coupled to a bias line.

16. The apparatus of claim 15, wherein said bias line comprises a grounded line.

17. The apparatus of claim 15, further comprising:
a current source to generate a reference current between said third drain and said first drain;
a differential amplifier including a first input terminal coupled to said third drain, a second input terminal coupled to said first drain, and an output terminal coupled to said fifth gate.

18. The apparatus of claim 14, further comprising a fifth FET including a fifth source, a fifth gate, and a fifth drain, wherein said fifth drain is coupled to said first and third sources, and said fifth source is coupled to a bias line.

19. The apparatus of claim 14, comprising a polyphase filter including a plurality of said transconductance cell.

20. The apparatus of claim 14, wherein said polyphase filter is configured as a low pass filter.

21. The apparatus of claim 14, wherein said polyphase filter is configured as a band pass filter.
